(19) United States
(12) Patent Application Publication
(10) Pub. No.: US 2018/0219162 A1
(43) Pub. Date: Aug. 2, 2018

(54) FOLDABLE OLED DISPLAY DEVICE

(71) Applicant: Wuhan China Star Optoelectronics Technology Co., Ltd., Wuhan City (CN)

(72) Inventor: Yuejun Tang, Wuhan City (CN)

(21) Appl. No.: 15/125,188

(22) PCT Filed: Jul. 27, 2016
(86) PCT No.: PCT/CN2016/091811

§ 371 Date: Sep. 12, 2016

(30) Foreign Application Priority Data
Jul. 12, 2016 (CN) 201610545359.6

(51) Int. Cl. H01L 51/00; H01L 27/32; H01L 51/52

(52) U.S. Cl. CPC H01L 51/0097; H01L 51/5203; H01L 27/3246

(57) ABSTRACT

The present invention provides a foldable OLED display device, which includes a flexible substrate (1), an OLED layer (2) formed on the flexible substrate (1), and a package layer (3) formed on the OLED layer (2). The flexible substrate (1) includes at least a first light emission zone (11), a second light emission zone (12), and a folding zone (13) located between the first light emission zone (11) and the second light emission zone (12). The OLED layer (2) includes at least a first OLED light emission component (21) located on the first light emission zone (11) and a second OLED light emission component (22) located on the second light emission zone (12). The first OLED light emission component (21) and the second OLED light emission component (22) are OLD components of different types so that the foldable OLED display device has at least two displaying surfaces to enrich function and application scenario of the OLED display for satisfying the needs of different viewers observing different displayed images at the same time.

### BACKGROUND OF THE INVENTION

### 1. Field of the Invention

The present invention relates to the field of display technology, and in particular to an foldable organic light emitting display (OLED) device.

### 2. The Related Arts

Flat panel display devices have various advantages, such as thin device body, lower power consumption, and being free of radiation, and are thus widely used. The flat panel display devices that are currently used include liquid crystal displays (LCDs) and organic light emitting displays (OLEDs).

The OLED possesses various advantageous properties, such as being self-luminous, requiring no light source, high contrast, reduced thickness, wide view angle, fast response speed, being applicable to flexible panels, wide operation temperature range, and simple structure and manufacturing process, and is thus considered an emerging application technology for the next generation of flat panel displays.

An OLED display device generally comprises: a substrate, an anode arranged on the substrate, a hole injection layer formed on the anode, a hole transportation layer formed on the hole injection layer, an emissive layer formed on the hole transportation layer, an electron transportation layer formed on the emissive layer, an electron injection layer formed on the electron transportation layer, and a cathode formed on the electron injection layer. The operation of the OLED display device for light emission is that a semiconductor material and an organic light emitting material, when driven by an electric field, allow a carrier flow to inject therein and combine to achieve emission of light. Specifically, the OLED display device often involves an ITO pixel electrode and a metal electrode to respectively serve as the anode and the cathode of the device and when driven by a predetermined voltage, electrons and holes are respectively injected from the anode and the cathode into the electron transportation layer and the hole transportation layer such that the electrons and the holes migrate through the electron transportation layer and the hole transportation layer into the emissive layer and they meet each other in the emissive layer to form excitons and excite light emission molecules, allowing the later to emit visible light through radiation relaxation.

Heretofore, a regular OLED display device has one single light emission surface and viewers can only watch a display panel from the light emission surface. Also, the light emission surface usually has a size that is fixed and invariable. However, in certain applications, there may be two viewers who want to watch different messages, programs, or images at the same time, or who need to watch a scene on the opposite side of the display while reading a message displayed on the display, and such needs of the viewers cannot be easily satisfied. In view of such a problem, a double-side-displaying OLED display device has been proposed, but such a double-side-displaying OLED display device must involve two OLED display screens and two sets of driver systems respectively corresponding thereto, so that the cost is relatively high and the size is also large, making it adverse for carrying and easily damaging the displays in moving. Further, the double-side-displaying OLED display device cannot satisfy a viewer's need for watching a scene on the opposite side of the display while reading a message displayed on the display.

### SUMMARY OF THE INVENTION

An object of the present invention is to provide a foldable organic light emitting display (OLED) device, which comprises multiple foldable displaying surfaces, which help enrich functionality and application scenario of an OLED display device and satisfy a need for multiple viewers simultaneously watching multiple images displayed, and also allow for easy carrying of the OLED display device.

To achieve the above object, the present invention provides a foldable OLED display device, which comprises: a flexible substrate, an OLED layer formed on the flexible substrate, and a package layer formed on the OLED layer;

the flexible substrate comprising at least a first light emission zone, a second light emission zone, and a folding zone located between the first light emission zone and the second light emission zone;

the OLED layer comprising at least a first OLED light emission component located on the first light emission zone and a second OLED light emission component located on the second light emission zone;

the first OLED light emission component being one of a top emission OLED component, a bottom emission OLED component, and a transparent OLED component, the second OLED light emission component being one of a top emission OLED component, a bottom emission OLED component, and a transparent OLED component and different from the first OLED light emission component;

wherein to fold, the flexible substrate is bent along the folding zone to have the first OLED light emission component and the second OLED light emission component overlapping each other and stacked together.

The first OLED light emission component and the second OLED light emission component each comprise a buffer layer formed on the flexible substrate, a thin-film transistor formed on the buffer layer, a planarization layer covering the thin-film transistor, a bottom electrode formed on the planarization layer and electrically connected to the thin-film transistor, an organic emissive layer formed on the bottom electrode, a pixel definition layer formed on an edge of the bottom electrode and the planarization layer and enclosing the organic emissive layer, and a top electrode formed on the pixel definition layer and the organic emissive layer.

The first OLED light emission component is a top emission OLED component in which the bottom electrode is reflective electrode and the top electrode is a transparent electrode; and

the second OLED light emission component is a bottom emission OLED component in which the bottom electrode is a transparent electrode and the top electrode is a reflective electrode.

Alternatively, the first OLED light emission component is a top emission OLED component in which the bottom electrode is a reflective electrode and the top electrode is a transparent electrode; and

the second OLED light emission component is a transparent OLED component, in which the bottom electrode and the top electrode are both transparent electrodes.

Alternatively, the first OLED light emission component is a bottom emission OLED component, in which the bottom electrode is a transparent electrode and the top electrode is a reflective electrode; and

the second OLED light emission component is a transparent OLED component, in which the bottom electrode and the top electrode are both transparent electrodes.

The flexible substrate has a thickness in the folding zone that is smaller than a thickness of the flexible substrate in the first light emission zone and the second light emission zone.

The package layer is formed of a material comprising one of glass, an organic film, an inorganic film, and a metal foil, or a combination of multiple ones thereof.

The package layer is formed of a material comprising an organic film, an inorganic film, or a combination of an organic film and an inorganic film and a portion of the package layer located in the folding zone is attached to the flexible substrate.

The folding zone comprises a connection wiring line formed thereon and the first OLED light emission component and the second OLED light emission component are connected to each other by the connection wiring line.

The first OLED light emission component and the second OLED light emission component are controllable by the same circuit driving system.

The present invention also provides a foldable OLED display device, which comprises: a flexible substrate, an OLED layer formed on the flexible substrate, and a package layer formed on the OLED layer;

the flexible substrate comprising at least a first light emission zone, a second light emission zone, and a folding zone located between the first light emission zone and the second light emission zone;

the OLED layer comprising at least a first OLED light emission component located on the first light emission zone and a second OLED light emission component located on the second light emission zone;

the first OLED light emission component being one of a top emission OLED component, a bottom emission OLED component, and a transparent OLED component, the second OLED light emission component being one of a top emission OLED component, a bottom emission OLED component, and a transparent OLED component and different from the first OLED light emission component;

wherein to fold, the flexible substrate is bent along the folding zone to have the first OLED light emission component and the second OLED light emission component overlapping each other and stacked together;

wherein the first OLED light emission component and the second OLED light emission component each comprise a buffer layer formed on the flexible substrate, a thin-film transistor formed on the buffer layer, a planarization layer covering the thin-film transistor, a bottom electrode formed on the planarization layer and electrically connected to the thin-film transistor, an organic emissive layer formed on the bottom electrode, a pixel definition layer formed on an edge of the bottom electrode and the planarization layer and enclosing the organic emissive layer, and a top electrode formed on the pixel definition layer and the organic emissive layer; and

wherein the package layer is formed of a material comprising one of glass, an organic film, an inorganic film, and a metal foil, or a combination of multiple ones thereof.

The efficacy of the present invention is that the present invention provides a foldable OLED display device. The foldable OLED display device comprises: a flexible substrate, an OLED layer formed on the flexible substrate, and a package layer formed on the OLED layer, wherein the flexible substrate comprises at least a first light emission zone, a second light emission zone, and a folding zone located between the first light emission zone and the second light emission zone. The OLED layer comprises at least a first OLED light emission component located on the first light emission zone and a second OLED light emission component located on the second light emission zone. Further, the first OLED light emission component is arranged as one of a top emission OLED component, a bottom emission OLED component, and a transparent OLED component and the second OLED light emission component is arranged as one of a top emission OLED component, a bottom emission OLED component, and a transparent OLED component and different from the first OLED light emission component, so that the foldable OLED display device is provided with at least two displaying surfaces to enrich the function and application scenario of an OLED display device for meeting the need for different viewers watching different displayed images at the same time and also allowing the flexible substrate to bend along the folding zone to have the first OLED light emission component and the second OLED light emission component overlapping together for easy carrying.

### BRIEF DESCRIPTION OF THE DRAWINGS

The features and technical contents of the present invention will be better understood by referring to the following detailed description and drawings the present invention. However, the drawings are provided for the purpose of reference and illustration and are not intended to limit the scope of the present invention.

In the drawing:

FIG. 1 is a schematic view illustrating a first example of a foldable organic light emitting display (OLED) device according to the present invention;

FIG. 2 is a schematic view illustrating a second example of the OLED display device according to the present invention;

FIG. 3 is a schematic view illustrating a third example of the OLED display device according to the present invention;

FIG. 4 is a schematic view illustrating a fourth example of the OLED display device according to the present invention;

FIG. 5 is a schematic view illustrating a first example of a top emission OLED component of the foldable OLED display device according to the present invention;

FIG. 6 is a schematic view illustrating a second example of the top emission OLED component of the foldable OLED display device according to the present invention;

FIG. 7 is a schematic view illustrating a bottom emission OLED component of the foldable OLED display device according to the present invention;

FIG. 8 is a schematic view illustrating a first example of a transparent OLED component of the foldable OLED display device according to the present invention;

FIG. 9 is a schematic view illustrating a second example of a transparent OLED component of the foldable OLED display device according to the present invention;

FIGS. 10 and 11 are schematic views illustrating light paths of a foldable LED display device according to the present invention that comprises a top emission OLED component and a bottom emission OLED component;

FIG. 12 is a schematic view illustrating light paths of a foldable LED display device according to the present invention that comprises a top emission OLED component and a transparent OLED component; and

FIG. 13 is a schematic view illustrating light paths of a foldable LED display device according to the present invention that comprises a bottom emission OLED component and a transparent OLED component.

### DETAILED DESCRIPTION OF THE PREFERRED EMBODIMENTS

To further expound the technical solution adopted in the present invention and the advantages thereof, a detailed description is given to a preferred embodiment of the present invention with reference to the attached drawings.

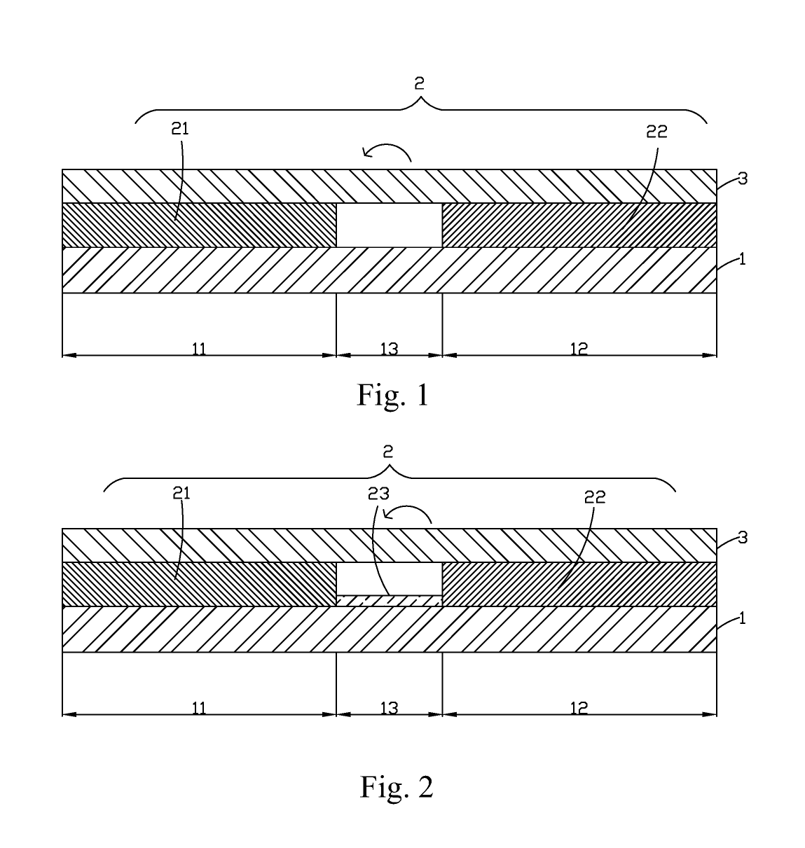

Referring to FIG. 1, the present invention provide a foldable organic light emitting display (OLED) device, which comprises: a flexible substrate 1, an OLED layer 2 formed on the flexible substrate 1, and a package layer 3 formed on the OLED layer 2.

The flexible substrate 1 comprises: a first light emission zone 11, a second light emission zone 12, and a folding zone 13 located between the first light emission zone 11 and the second light emission zone 12.

The OLED layer 2 comprises: a first OLED light emission component 21 located on the first light emission zone 11 and a second OLED light emission component 22 located on the second light emission zone 12.

The first OLED light emission component 21 can be one of a top emission OLED component, a bottom emission OLED component, and a transparent OLED component. The second OLED light emission component 22 can be one of a top emission OLED component, a bottom emission OLED component, and a transparent OLED component and is different from the first OLED light emission component 21.

To fold, the flexible substrate 1 is bent about the folding zone 13 to have the first OLED light emission component 21 and the second OLED light emission component 22 overlapping each other.

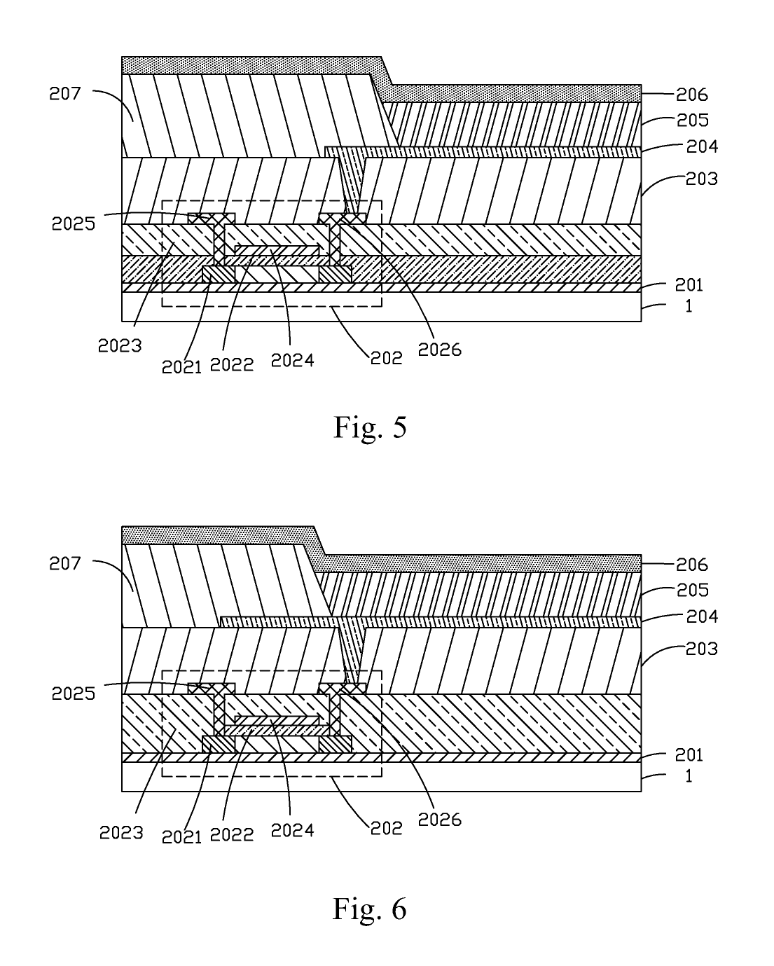

Specifically, referring to FIGS. 5-9, the first OLED light emission component 21 and the second OLED light emission component 22 each comprise: a buffer layer 201 formed on the flexible substrate 1, a thin-film transistor 202 formed on the buffer layer 201, a planarization layer 203 covering the thin-film transistor 202, a bottom electrode 204 formed on the planarization layer 203 and electrically connected to the thin-film transistor 202, an organic emissive layer 205 formed on the bottom electrode 204, a pixel definition layer 207 formed on an edge of the bottom electrode 204 and the planarization layer 203 and enclosing the organic emissive layer 205, and a top electrode 206 formed on the pixel definition layer 207 and the organic emissive layer 205.

It is noted here that the thin-film transistor 202 may be of a type and a structure that are selected according to requirements, such as a single-crystal thin-film transistor, a low-temperature poly-silicon thin-film transistor, or an oxide semiconductor thin-film transistor and the structure thereof can be top gate type, bottom gate type, or other types. Preferably, as shown in FIGS. 5-9, the thin-film transistor 202 is a top gate low-temperature poly-silicon thin-film transistor, which comprises: an active layer 2021 formed on the buffer layer 201, a gate insulation layer 2022 formed on the active layer 2021 and the buffer layer 201, a gate electrode 2024 formed on the gate insulation layer 2022 and located above the active layer 2021, an interlayer insulation layer 2023 formed on the gate electrode 2024 and the gate insulation layer 2022, and a source electrode 2025 and a drain electrode 2026 formed on the interlayer insulation layer 2023, wherein the source electrode 2025 and the drain electrode 2026 are respectively set in contact with two ends of the active layer 2021 through vias formed through the interlayer insulation layer 2023 and the gate insulation layer 2022 and the bottom electrode 204 is set in contact with the drain electrode 2026 through a via formed through the planarization layer 203.

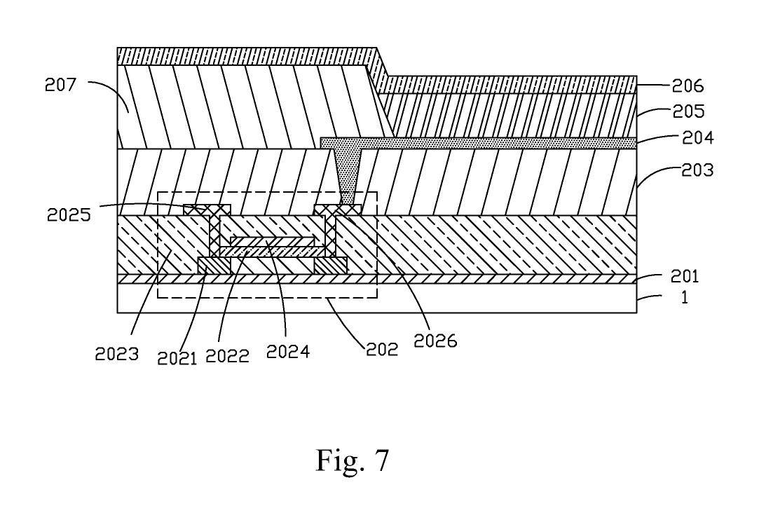

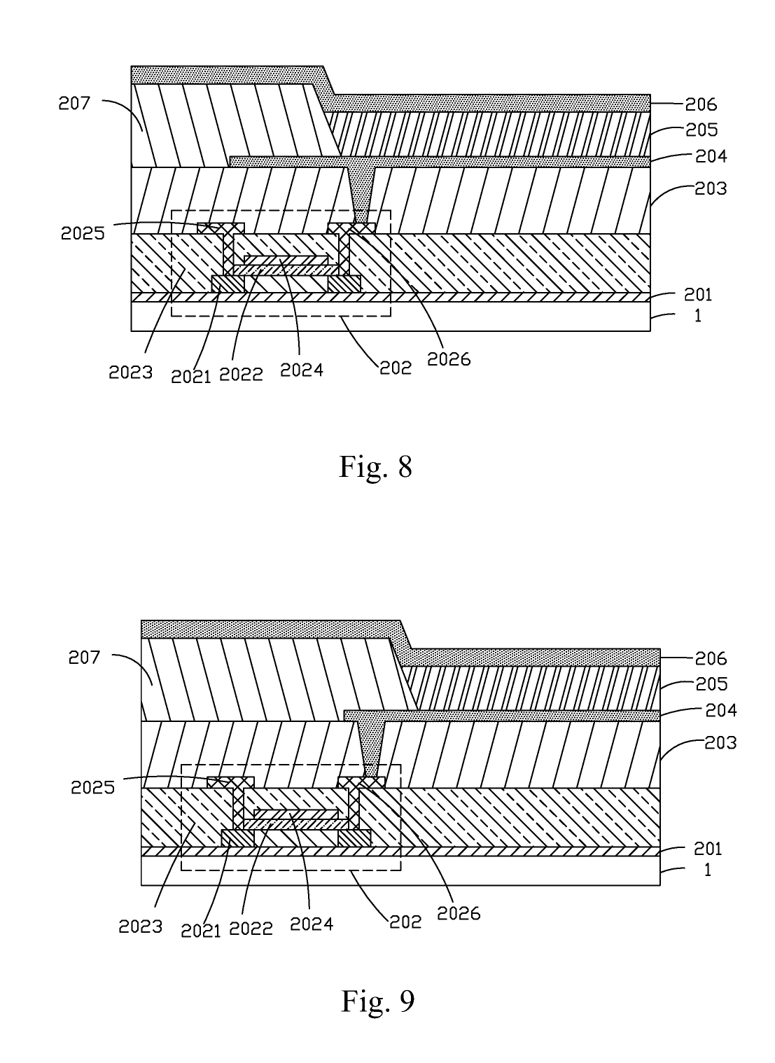

Specifically, referring to FIGS. 5 and 6, in case that the OLED light emission component is a top emission OLED component, the bottom electrode 204 thereof is a reflective electrode and the top electrode 206 is a transparent electrode. Referring to FIG. 7, in case that the OLED light emission component is a bottom emission OLED component, the bottom electrode 204 thereof is a transparent electrode and the top electrode 206 is a reflective electrode. Referring to FIGS. 8 and 9, in case that the OLED light emission component is a transparent OLED component, the bottom electrode 204 and the top electrode 206 thereof are both a transparent electrode. Referring to FIGS. 6 and 8, the bottom electrode 204, the organic emissive layer 205, and the top electrode 206 of the top emission OLED component and the transparent OLED component can be extended to a location above the thin-film transistor 202 in order to enlarge a light emission surface area of a pixel. Further, the bottom electrode 204 and the top electrode 206 of the transparent OLED component may have different transmission rates so as to allow the sides of the transparent OLED components respectively corresponding to the bottom electrode 204 and the top electrode 206 to emit different intensities of light.

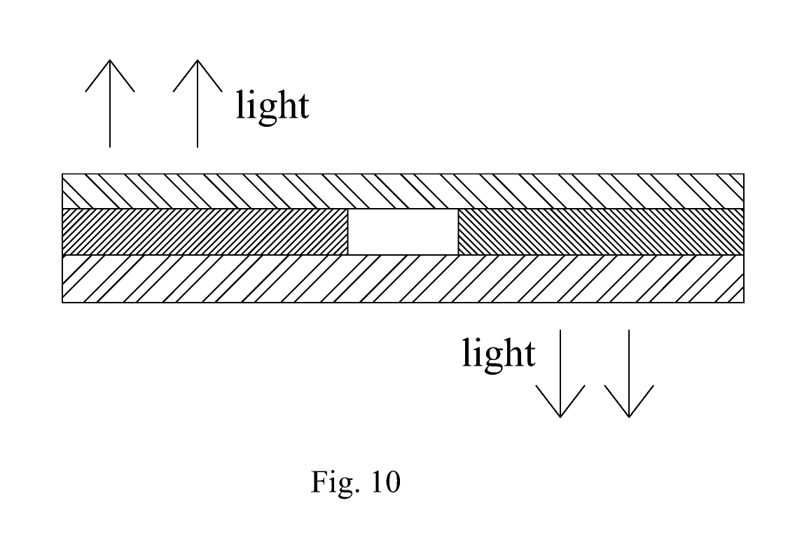

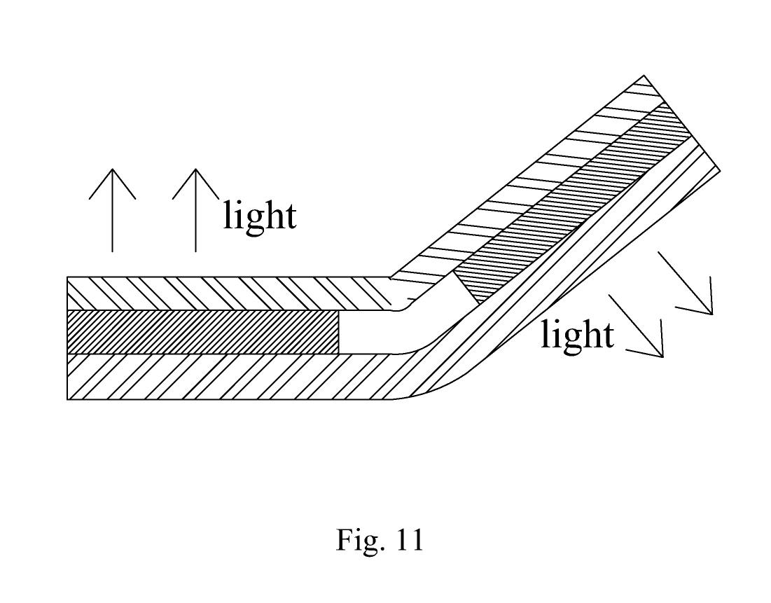

Optionally, referring to FIG. 10, the first OLED light emission component 21 can be a top emission OLED component, while the second OLED light emission component 22 is a bottom emission OLED component, so that the foldable OLED display device allows for observation of different displayed images respectively on the side associated with the flexible substrate 1 and the side associated with the package layer 3. Also, referring to FIG. 11, through adjusting or changing an include angle between the first OLED light emission component 21 and the second OLED light emission component 22, view angles of the two displayed images can be adjusted.

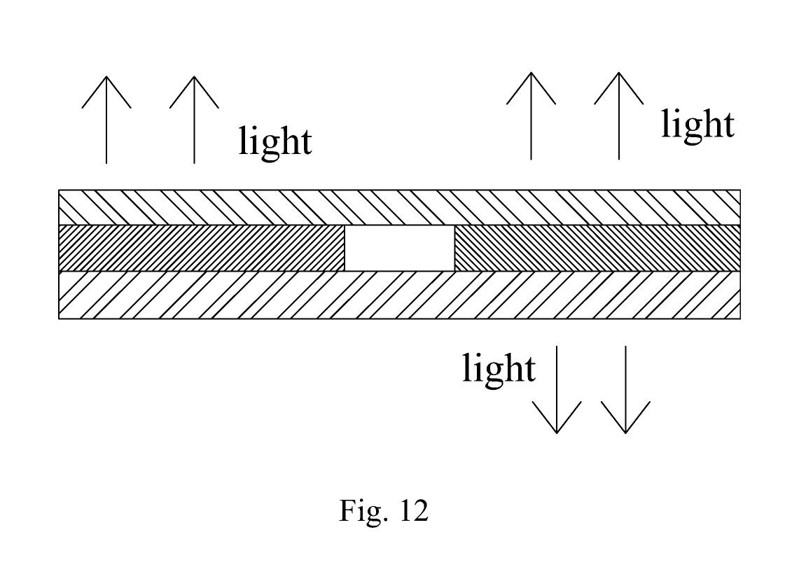

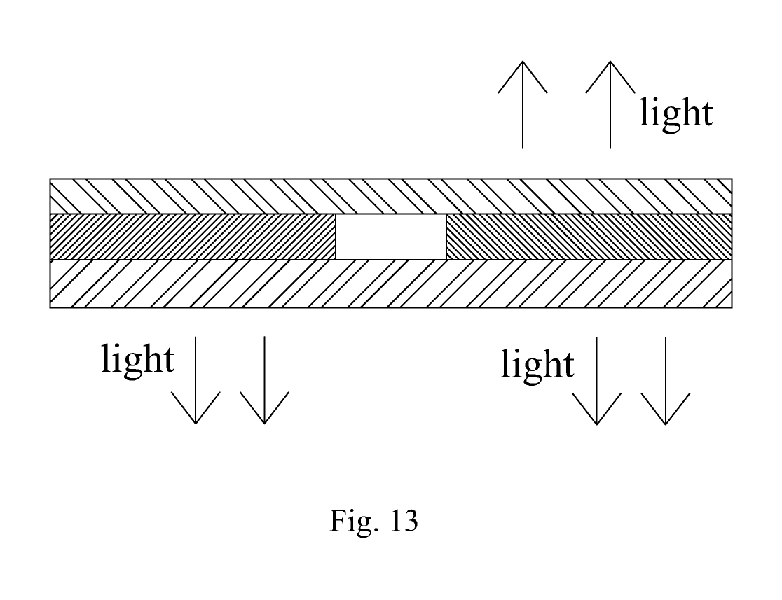

Optionally, referring to FIG. 12, the first OLED light emission component 21 can be a top emission OLED component, while the second OLED light emission component 22 is a transparent OLED component, so that the foldable OLED display device allows for observation of a displayed image of the first OLED light emission component 21 on the side associated with the package layer 3 and also allows for observation of a display image of the second OLED light emission component 22 on the side associated with the flexible substrate 1 and the side associated with the package layer 3 and further allows for observation of a scene image behind the display by seeing through the second OLED light emission component 22. In this case, it is similarly possible to adjust view angles of the two displayed images by adjusting the included angle between the first OLED light emission component 21 and the second OLED light emission component 22.

Optionally, the first OLED light emission component 21 can be a bottom emission OLED component, while the second OLED light emission component 22 is a transparent OLED component, so that the foldable OLED display device allows for observation a displayed image of the first OLED light emission component 21 on the side associated with the flexible substrate 1 and also allows for observation of a display image of the second OLED light emission component 22 on the side associated with the flexible substrate 1 and the side associated with the package layer 3 and further allows for observation of a scene image behind the display by seeing through the second OLED light emission component 22. In this case, it is similarly possible to adjust view angles of the two displayed images by adjusting the included angle between the first OLED light emission component 21 and the second OLED light emission component 22.

It is noted that referring to FIG. 2, wherein FIG. 2 shows a second example of the present invention, to reduce the number of circuits integrated, the number of solder pads, and number of soldering (bonding) processes involved to thereby save cost, when the first OLED light emission component 21 and the second OLED light emission component 22 are of the same size of pixel, the folding zone 13 may be provided with a connection wiring line 23, such that the connection wiring line 23 connects the first OLED light emission component 21 and the second OLED light emission component 22 together to allow the first OLED light emission component 21 and the second OLED light emission component 22 to be simultaneously driven through the same soldering pad zone. Preferably, when the pixel sizes and the pixel light emission areas of both the first OLED light emission component 21 and the second OLED light emission component 22 are identical, the first OLED light emission component 21 and the second OLED light emission component 22 can be driven through the same soldering pad zone and the same driving system. When the pixel sizes of the first OLED light emission component 21 and the second OLED light emission component 22 are identical but the pixel light emission areas are different, the first OLED light emission component 21 and the second OLED light emission component 22 can be driven respectively by two sub driving systems through the same soldering pad zone. It is also possible to be the same as the first example illustrated in FIG. 1, where the folding zone 13 is not provided with a connection wiring line 23, and the first OLED light emission component 21 and the second OLED light emission component 22 are respectively connected to two soldering pad zones and are respectively controlled by two independent driving systems. The locations of the soldering pad zones can be selected according to requirements and are not limited to any specific fixed sites.

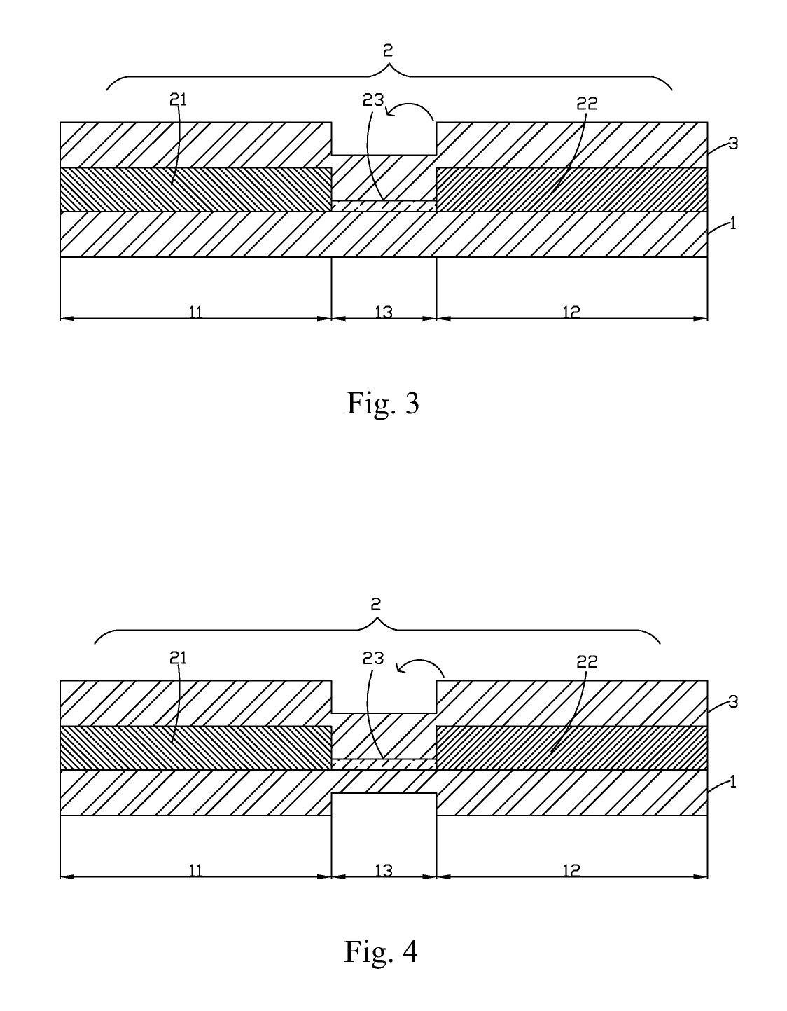

Further, to reduce the thickness of the folding portion in order to further ease folding, as shown in FIG. 3, in a third example of the present invention, it is possible to adopt thin film packaging to have a portion of the package layer 3 located above the folding zone 13 attached to the flexible substrate 1 for reducing the thickness at the folding site. Further, referring to FIG. 4, in a fourth example of the present invention, in addition to having the portion of the package layer 3 located above the folding zone 13 attached to the flexible substrate 1, the flexible substrate 1 is provided with a thickness in the folding zone 13 that is smaller than a thickness of the flexible substrate 1 in the first light emission zone 11 and the second light emission zone 12 in order to further reduce the thickness at the folding site.

Specifically, the flexible substrate 1 can be made of a material comprising one of flexible glass, an organic film, an in organic film, and a metal foil, or a combination of multiple ones thereof. The package layer 3 can be formed of a material comprising glass, an organic film, an in organic film, and a metal foil, or a combination of multiple ones thereof. In case that thin film packaging is adopted, the package layer 3 can be formed of a material comprising an organic film, an in organic film, or a combination of an organic film and an inorganic film.

Specifically, in case that the bottom electrode 204 is a transparent electrode, the material thereof can be indium tin oxide, indium zinc oxide, zinc oxide, or indium oxide. In case that the bottom electrode 204 is a reflective electrode, it may comprise: a reflective layer that is arranged distant from the organic emissive layer and a transparent layer that is arranged adjacent to the organic emissive layer, wherein the reflective layer is formed of a material comprising an alloy or a compound of one or multiple ones of silver, magnesium, aluminum, platinum, palladium, gold, nickel, neodymium, iridium, and chromium and the transparent layer is formed of a material comprising: indium tin oxide, indium zinc oxide, zinc oxide, or indium oxide. In case that the top electrode 206 is a transparent electrode, it comprises an intermediate layer and an assisting electrode or a bus electrode line, wherein the intermediate layer is formed of a material comprising lithium, calcium, aluminum, magnesium, a combination of lithium fluoride and calcium, or a combination of lithium fluoride and aluminum, or a compound of the above materials. The assisting electrode or bus electrode line is formed of a material comprising indium tin oxide, indium zinc oxide, zinc oxide, and indium oxide. In case that the top electrode 206 is a reflective electrode, the material thereof can be lithium, calcium, aluminum, magnesium, a combination of lithium fluoride and calcium, or a combination of lithium fluoride and aluminum, or a compound of the above materials, or an alloy of the above materials.

Specifically, the thin-film transistors 202, the planarization layers 203, and the organic emissive layers 205 of the first OLED light emission component 21 and the second OLED light emission component 22 can be formed simultaneously. The top electrode 206 and the bottom electrode 204 can also be formed simultaneously when their materials are the same. Since the organic emissive layers 205 of the first OLED light emission component 21 and the second OLED light emission component 22 are formed simultaneously, the light emission materials of the first OLED light emission component 21 and the second OLED light emission component 22 are the same so that when the sizes and driving signals of the organic emissive layers 205 are made the same, light emission intensity of unit areas thereof would be the same whereby it is possible to achieve a bettered display effect of the transparent OLED component by adjusting the areas of the organic emissive layers 205 of the first OLED light emission component 21 and the second OLED light emission component 22, magnitudes of electrical signals, and reflectivity of the reflective layers.

It is noted that in case that the folding zone 13 has a relatively large width (greater than 5 mm) and positioning alignment is difficult, the folding zone 13 may be subjected to constrain of the shape thereof by means of additional assisting device (such as a casing).

It is appreciated that the present invention is not limited to an arrangement including only two OLED components and one folding zone, and it is possible to arrange more light emission zones and folding zones on the flexible substrate 1 with each of the light emission zones being formed thereon with more OLED components and each of the folding zones provided with a width that is set to be the same or different according to actual needs. Each of the folding zones may have a bending direction that is the same or different. For example, in an arrangement comprising three light emission zones and two folding zones sequentially lined up in a horizontal direction, the two folding zones may be arranged to have the same width and the left-side light emission zone folded onto an upper surface of the central light emission zone and the right-side light emission zone folded onto a lower surface of the central light emission zone to achieve folding of three light emission zones. Alternatively, the left-side folding zone may be provided with a width that is greater than a width of the right-side folding zone and the right-side light emission zone is first folded onto an upper surface of the central light emission zone and then, the left-side folding zone is folded onto an upper surface of the right-side light emission zone to achieve folding of three light emission zones. Other factors including selection of the type of OLED display component, arrangement of connection wiring line in the folding zone, reduction of the thickness of the folding zone, and selections of all materials involved are similar to those associated with the examples and embodiments described above so that repeated description will be omitted here.

In summary, the present invention provides a foldable OLED display device. The foldable OLED display device comprises: a flexible substrate, an OLED layer formed on the flexible substrate, and a package layer formed on the OLED layer, wherein the flexible substrate comprises at least a first light emission zone, a second light emission zone, and a folding zone located between the first light emission zone and the second light emission zone. The OLED layer comprises at least a first OLED light emission component located on the first light emission zone and a second OLED light emission component located on the second light emission zone. Further, the first OLED light emission component is arranged as one of a top emission OLED component, a bottom emission OLED component, and a transparent OLED component and the second OLED light emission component is arranged as one of a top emission OLED component, a bottom emission OLED component, and a transparent OLED component and different from the first OLED light emission component, so that the foldable OLED display device is provided with at least two displaying surfaces to enrich the function and application scenario of an OLED display device for meeting the need for different viewers watching different displayed images at the same time and also allowing the flexible substrate to bend along the folding zone to have the first OLED light emission component and the second OLED light emission component overlapping together for easy carrying.

Based on the description given above, those having ordinary skills of the art may easily contemplate various changes and modifications of the technical solution and technical ideas of the present invention and all these changes and modifications are considered within the protection scope of right for the present invention as defined in the appended claims.

What is claimed is:

1. A foldable organic light emitting display (OLED) display device, comprising:
a flexible substrate, an OLED layer formed on the flexible substrate, and a package layer formed on the OLED layer;
the flexible substrate comprising at least a first light emission zone, a second light emission zone, and a folding zone located between the first light emission zone and the second light emission zone;
the OLED layer comprising at least a first OLED light emission component located on the first light emission zone and a second OLED light emission component located on the second light emission zone;
the first OLED light emission component being one of a top emission OLED component, a bottom emission OLED component, and a transparent OLED component, the second OLED light emission component being one of a top emission OLED component, a bottom emission OLED component, and a transparent OLED component and different from the first OLED light emission component;
wherein to fold, the flexible substrate is bent along the folding zone to have the first OLED light emission component and the second OLED light emission component overlapping each other and stacked together.

2. The foldable OLED display device as claimed in claim 1, wherein the first OLED light emission component and the second OLED light emission component each comprise a buffer layer formed on the flexible substrate, a thin-film transistor formed on the buffer layer, a planarization layer covering the thin-film transistor, a bottom electrode formed on the planarization layer and electrically connected to the thin-film transistor, an organic emissive layer formed on the bottom electrode, a pixel definition layer formed on an edge of the bottom electrode and the planarization layer and enclosing the organic emissive layer, and a top electrode formed on the pixel definition layer and the organic emissive layer.

3. The foldable OLED display device as claimed in claim 2, wherein the first OLED light emission component is a top emission OLED component in which the bottom electrode is reflective electrode and the top electrode is a transparent electrode; and
the second OLED light emission component is a bottom emission OLED component in which the bottom electrode is a transparent electrode and the top electrode is a reflective electrode.

4. The foldable OLED display device as claimed in claim 2, wherein the first OLED light emission component is a top emission OLED component in which the bottom electrode is a reflective electrode and the top electrode is a transparent electrode; and
the second OLED light emission component is a transparent OLED component, in which the bottom electrode and the top electrode are both transparent electrodes.

5. The foldable OLED display device as claimed in claim 2, wherein the first OLED light emission component is a bottom emission OLED component, in which the bottom electrode is a transparent electrode and the top electrode is a reflective electrode; and
the second OLED light emission component is a transparent OLED component, in which the bottom electrode and the top electrode are both transparent electrodes.

6. The foldable OLED display device as claimed in claim 1, wherein the flexible substrate has a thickness in the folding zone that is smaller than a thickness of the flexible substrate in the first light emission zone and the second light emission zone.

7. The foldable OLED display device as claimed in claim 1, wherein the package layer is formed of a material comprising one of glass, an organic film, an inorganic film, and a metal foil, or a combination of multiple ones thereof.

8. The foldable OLED display device as claimed in claim 7, wherein the package layer is formed of a material comprising an organic film, an inorganic film, or a combination of an organic film and an inorganic film and a portion of the package layer located in the folding zone is attached to the flexible substrate.

9. The foldable OLED display device as claimed in claim 1, wherein the folding zone comprises a connection wiring line formed thereon and the first OLED light emission component and the second OLED light emission component are connected to each other by the connection wiring line.

10. The foldable OLED display device as claimed in claim 9, wherein the first OLED light emission component and the second OLED light emission component are controllable by the same circuit driving system.

11. A foldable organic light emitting display (OLED) display device, comprising:
a flexible substrate, an OLED layer formed on the flexible substrate, and a package layer formed on the OLED layer;
the flexible substrate comprising at least a first light emission zone, a second light emission zone, and a folding zone located between the first light emission zone and the second light emission zone;
the OLED layer comprising at least a first OLED light emission component located on the first light emission zone and a second OLED light emission component located on the second light emission zone;
the first OLED light emission component being one of a top emission OLED component, a bottom emission OLED component, and a transparent OLED component, the second OLED light emission component being one of a top emission OLED component, a bottom emission OLED component, and a transparent OLED component and different from the first OLED light emission component;
wherein to fold, the flexible substrate is bent along the folding zone to have the first OLED light emission component and the second OLED light emission component overlapping each other and stacked together;
wherein the first OLED light emission component and the second OLED light emission component each comprise a buffer layer formed on the flexible substrate, a thin-film transistor formed on the buffer layer, a planarization layer covering the thin-film transistor, a bottom electrode formed on the planarization layer and electrically connected to the thin-film transistor, an organic emissive layer formed on the bottom electrode, a pixel definition layer formed on an edge of the bottom electrode and the planarization layer and enclosing the organic emissive layer, and a top electrode formed on the pixel definition layer and the organic emissive layer; and
wherein the package layer is formed of a material comprising one of glass, an organic film, an inorganic film, and a metal foil, or a combination of multiple ones thereof.

12. The foldable OLED display device as claimed in claim 11, wherein the first OLED light emission component is a top emission OLED component in which the bottom electrode is reflective electrode and the top electrode is a transparent electrode; and
the second OLED light emission component is a bottom emission OLED component in which the bottom electrode is a transparent electrode and the top electrode is a reflective electrode.

13. The foldable OLED display device as claimed in claim 11, wherein the first OLED light emission component is a top emission OLED component in which the bottom electrode is a reflective electrode and the top electrode is a transparent electrode; and
the second OLED light emission component is a transparent OLED component, in which the bottom electrode and the top electrode are both transparent electrodes.

14. The foldable OLED display device as claimed in claim 11, wherein the first OLED light emission component is a bottom emission OLED component, in which the bottom electrode is a transparent electrode and the top electrode is a reflective electrode; and
the second OLED light emission component is a transparent OLED component, in which the bottom electrode and the top electrode are both transparent electrodes.

15. The foldable OLED display device as claimed in claim 11, wherein the flexible substrate has a thickness in the folding zone that is smaller than a thickness of the flexible substrate in the first light emission zone and the second light emission zone.

16. The foldable OLED display device as claimed in claim 11, wherein the package layer is formed of a material comprising an organic film, an inorganic film, or a combination of an organic film and an inorganic film and a portion of the package layer located in the folding zone is attached to the flexible substrate.

17. The foldable OLED display device as claimed in claim 11, wherein the folding zone comprises a connection wiring line formed thereon and the first OLED light emission component and the second OLED light emission component are connected to each other by the connection wiring line.

18. The foldable OLED display device as claimed in claim 17, wherein the first OLED light emission component and the second OLED light emission component are controllable by the same circuit driving system.
